(19) United States
(12) Patent Application Publication
(10) Pub. No.: US 2025/0328602 A1
(43) Pub. Date: Oct. 23, 2025

(54) MEMORY SYSTEMS AND METHODS OF OPERATING MEMORY SYSTEMS

(71) Applicant: Yangtze Memory Technologies Co., Ltd., Wuhan (CN)

(72) Inventor: Zhiwei Zhuang, Wuhan (CN)

(21) Appl. No.: 18/806,413

(22) Filed: Aug. 15, 2024

(30) Foreign Application Priority Data
Apr. 22, 2024 (CN) 202410489403.0

(51) Int. Cl. G06F 17/16; G11C 16/04; H03M 7/30

(52) U.S. Cl. CPC G06F 17/16; H03M 7/3082; G11C 16/0483

(57) ABSTRACT

The present disclosure provides memory systems and methods of operating memory systems. An example memory system includes a memory and a controller. The memory is coupled with the controller. The controller is configured to: receive to-be-encoded data; acquire a check code vector of the to-be-encoded data based on the to-be-encoded data, wherein the check code vector is used for an accuracy check of the corresponding to-be-encoded data; and store an encoded codeword into the memory, wherein each encoded codeword includes the to-be-encoded data and the check code vector corresponding to the to-be-encoded data, and different encoded codewords corresponding to the to-be-encoded data with different numbers of information bits have different numbers of information bits.

### CROSS-REFERENCE TO RELATED APPLICATION

The present disclosure claims the benefit of priority to China Application No. 202410489403.0, filed on Apr. 22, 2024, the content of which is incorporated herein by reference in its entirety.

### TECHNICAL FIELD

The present disclosure relates to the technical field of data processing, and particularly to memory systems and methods of operating memory systems.

### BACKGROUND

A memory system, such as a flash (NAND), comprises a memory. The memory comprises a plurality of memory cells, and each memory cell may be used for data storage. An access read of stored data may be implemented by performing a read operation on the memory cell via a threshold voltage within a preset range.

### BRIEF DESCRIPTION OF THE DRAWINGS

In order to illustrate the technical solution in the present disclosure more clearly, the drawings to be used in some examples of the present disclosure will be briefly introduced below. Apparently, the drawings in the following description are only drawings of some examples of the present disclosure. Those of ordinary skills in the art may also obtain other drawings according to these drawings. In addition, the drawings in the following description may be regarded as schematic diagrams, instead of limitations to an actual size of a product, an actual flow of a method, an actual timing of a signal, etc. involved in the examples of the present disclosure.

FIG. 1 is a schematic module diagram I of an electronic device according to some examples.

FIG. 2 is a schematic module diagram of a memory card according to some examples.

FIG. 3 is a schematic module diagram of a solid state drive according to some examples.

FIG. 4 is a schematic diagram I of a memory according to some examples.

FIG. 5 is a schematic diagram II of a memory according to some examples.

FIG. 6 is a schematic module diagram of a memory system according to some examples.

FIG. 7 is a schematic diagram of a bit composition of an encoded codeword according to some examples.

FIG. 8 is a schematic diagram of an encoding process according to some examples.

FIG. 9 is a schematic diagram of a decoding process according to some examples.

FIG. 10 is a schematic module diagram II of an electronic device according to some examples.

FIG. 11 is a flow diagram I of a method of operating a memory system according to some examples.

FIG. 12 is a flow diagram II of a method of operating a memory system according to some examples.

FIG. 13 is a flow diagram III of a method of operating a memory system according to some examples.

### DETAILED DESCRIPTION

The technical solutions in some examples of the present disclosure will be described below clearly and completely in conjunction with the drawings. Apparently, the examples described are only part of, but not all of, the examples of the present disclosure. All other examples obtained by those of ordinary skills in the art based on the examples provided by the present disclosure should fall in the scope protected by the present disclosure.

Unless otherwise specified in the context, throughout the specification and the claims, the term “comprise” is interpreted as an open and inclusive meaning, i.e., “including, but not limited to”. In the description of the specification, the terms “one implementation”, “some implementations”, “one example”, or “some examples”, etc. are intended to indicate that particular features, structures, materials, or characteristics related to the embodiment or example are included in at least one embodiment or example of the present disclosure. The schematic representation of the above terms may not necessarily refer to the same embodiment or example. Furthermore, these particular features, structures, materials, or characteristics may be included in any one or more embodiments or examples in any suitable manner.

In the following, the terms “first” and “second” are only for the purpose of description, and cannot be construed as indicating or implying relative importance or implicitly indicating the number of indicated technical features. Thus, features defined by “first” and “second” may explicitly or implicitly comprise one or more of such features. In the description of the examples of the present disclosure, “a plurality of” means two or more, unless otherwise stated.

In describing some examples, the expressions “coupled” and “connected” and derivatives thereof may be used. For example, the term “connected” may be used in the description of some examples to indicate that two or more components have a direct physical contact or an electrical contact with each other. For another example, the term “coupled” may be used in the description of some examples to indicate that two or more components have a direct physical contact or electrical contact. However, the term “couple” may also mean that two or more components are not in direct contact with each other, but they still cooperate or interact with each other. The examples disclosed herein are not necessarily limited to the content herein.

“At least one of A, B, and C” and “at least one of A, B, or C” have the same meaning, both including the following combinations of A, B, and C: A alone, B alone, C alone, a combination of A and B, a combination of A and C, a combination of B and C, and a combination of A, B, and C.

The use of “suitable for” or “configured to” herein means open and inclusive language, and does not exclude a device suitable for performing or configured to perform additional tasks or steps.

In addition, the use of “based on” means openness and inclusiveness, as processes, steps, calculations, or other actions “based on” one or more conditions or values may be based on an additional condition or exceeded value in practice.

However, during actual working of the memory system, due to impacts of factors such as internal noise and channel variation of the flash, an abnormality in a threshold voltage distribution is caused easily, resulting in data read and write errors, and thereby affecting the reliability of data storage.

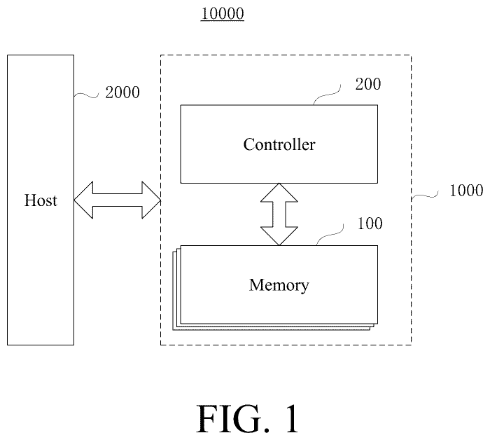

Examples of the present disclosure provide a memory system. The memory system may be applied to and packaged into different types of electronic devices, such as a mobile phone (e.g., a cellphone), a desktop computer, a tablet computer, a notebook computer, a server, an in-vehicle device, a gaming console, a printer, a positioning device, a wearable device (e.g., a smart watch, a smart band, smart glasses, etc.), a smart sensor, a mobile power supply, a Virtual Reality (VR) device, an Augmented Reality (AR) device, or any other suitable electronic devices having memories therein. As shown in FIG. 1, the electronic device 10000 comprises a memory system 1000 and a host 2000. The memory system 1000 comprises one or more memories 100 and a controller 200, and the controller 200 is coupled with the memory 100. The host 2000 may be a processor of the electronic device. In an example, the processor may be a chip, which may be particularly a Field Programmable Gate Array (FPGA), an Application Specific Integrated Circuit (ASIC), a System on Chip (SoC), a Central Processor Unit (CPU), a Network Processor (NP), a Digital Signal Processor (DSP), a Micro Controller Unit (MCU), a Programmable Logic Device (PLD), an Application Processor (AP), or other integrated chips.

According to some implementations, the controller 200 is coupled to the memory 100 and the host 2000, and configured to control the memory 100. The controller 200 can manage data stored in the memory 100 and communicate with the host 2000. In some implementations, the controller 200 is designed for operating in a low duty-cycle environment, such as a Secure Digital (SD) card, a Compact Flash (CF) card, a Universal Serial Bus (USB) flash drive, or other media for use in electronic devices such as a personal computer, a digital camera, or a mobile phone. In some implementations, the controller 200 is designed for operating in a high duty-cycle environment, such as a Solid State Drive (SSD) or an Embedded MultiMedia Card (eMMC), which is used as a data storage device for mobile electronic devices such as a smartphone, a tablet computer, or a laptop computer, and an enterprise memory array. The controller 200 may be further configured to control operations of the memory 100, such as read, erase, and program operations. The controller 200 may also be configured to manage various functions with respect to data stored or to be stored in the memory 100, including, but not limited to, bad-block management, garbage collection, logical-to-physical address conversion, wear leveling, etc. In some implementations, the controller 200 is further configured to process an Error Correction Code (ECC) with respect to data read from or written to the memory 100. The controller 200 may further perform any other suitable functions, e.g., formatting the memory 100. The controller 200 may communicate with an external device (e.g., the host 2000) according to a particular communication protocol. For example, the controller 200 may communicate with the external apparatus through at least one of various interface protocols, such as a USB protocol, a MultiMedia Card (MMC) protocol, a Peripheral Component Interconnection (PCI) protocol, a PCI Express (PCI-E) protocol, an Advanced Technology Attachment (ATA) protocol, a Serial ATA protocol, a Parallel ATA protocol, a Small Computer System Interface (SCSI) protocol, an Enhanced Small Device Interface (ESDI) protocol, an Integrated Drive Electronics (IDE) protocol, and a Firewire protocol, etc.

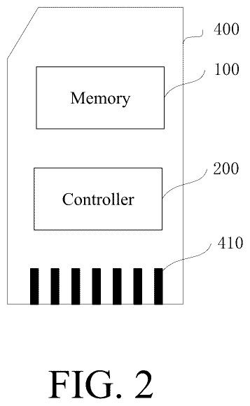

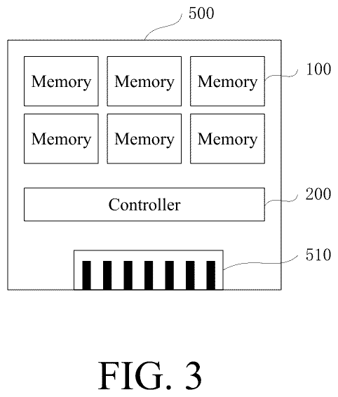

The controller 200 and the one or more memories 100 may be integrated into various types of storage devices, e.g., be included in the same package, such as a Universal Flash Storage (UFS) package or an eMMC package. That is, the memory system 1000 may be implemented and packaged into different types of final electronic products. In one example as shown in FIG. 2, the controller 200 and a single memory 100 may be integrated into a memory card 400. The memory card 400 may include a PC card (Personal Computer Memory Card International Association, PCMCIA), a CF card, a Smart Media (SM) card, a memory stick, a Multimedia card (MMC, RS-MMC, MMCmicro), an SD card (SD, miniSD, microSD, SDHC), and a UFS, etc. The memory card 400 may further comprise a memory card connector 410 coupling the memory card 400 with a host (e.g., the host 2000 in FIG. 1). In another example as shown in FIG. 3, the controller 200 and a plurality of memories 100 may be integrated into an SSD 500. The SSD 500 may further comprise an SSD connector 510 coupling the SSD 500 with a host (e.g., the host 2000 in FIG. 1). In some implementations, at least one of a storage capacity or an operation speed of the SSD 500 is greater than that of the memory card 400.

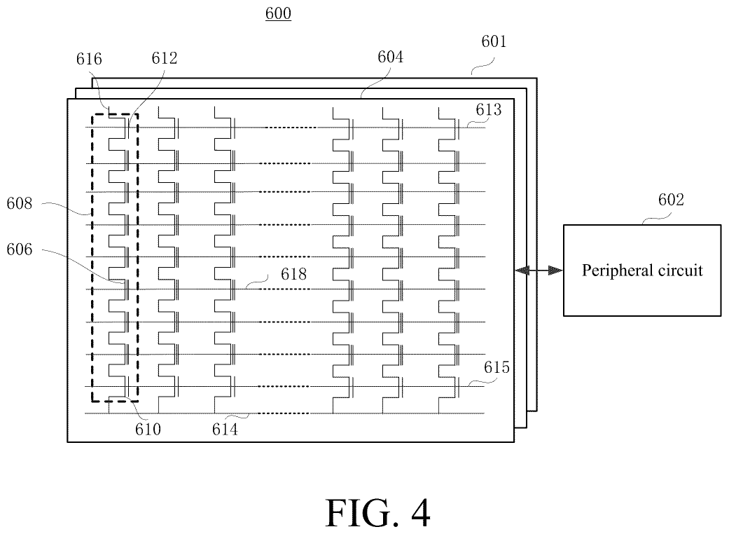

FIG. 4 illustrates a schematic circuit diagram of an example memory 600 comprising a peripheral circuit 602 according to some aspects of the present disclosure. The memory 600 may be an example of the memory 100 in FIG. 1. The memory 600 may comprise a memory cell array 601 and a peripheral circuit 602 coupled to the memory cell array 601. The memory cell array 601 may be a NAND flash memory cell array, wherein memory cells 606 are provided in an array of NAND memory strings 608 each extending vertically above a substrate (not shown). In some implementations, each NAND memory string 608 comprises a plurality of memory cells 606 coupled in series and stacked vertically. Each memory cell 606 can maintain a continuous analog value, such as voltage or charge, which depends on the number of electrons trapped within a region of the memory cell 606. Each memory cell 606 may be a floating gate memory cell that comprises a floating gate transistor, or a charge trap memory cell that comprises a charge trap transistor.

In some implementations, each memory cell 606 is a Single-Level Cell (SLC) that has two possible memory states (levels) and thus can store one bit of data. For example, a first memory state “0” may correspond to a threshold voltage in a first range, and a second memory state “1” may correspond to threshold voltage in a second range. In some implementations, each memory cell 606 is an xLC that may store more than one bit of data in more than four memory states (levels). For example, the xLC may store two bits per cell (Multi-Level Cell (MLC)), store three bits per cell (Triple-Level Cell (TLC)), or store four bits per cell (Quad-Level Cell (QLC)). Each xLC may be programmed to assume a range of possible nominal storage values (i.e., 2N pieces of N-bit data, such as a Gray code). In one example, the MLC may be programmed to assume one of three possible program levels from an erase state by writing one of three possible nominal storage values to the cell. A fourth nominal storage value may be used for the e rase state.

As shown in FIG. 4, each NAND memory string 608 may further comprise a Source Select Gate (SSG) transistor 610 at a source terminal thereof and a Drain Select Gate (DSG) transistor 612 at a drain terminal thereof. The SSG transistor 610 and the DSG transistor 612 may be configured to activate a selected NAND memory string 608 (a column of the array) during read and program operations. In some implementations, sources of the NAND memory strings 608 in the same block 604 are coupled through the same Source Line (SL) 614 (e.g., a common SL). In other words, according to some implementations, all the NAND memory strings 608 in the same block 604 have an Array Common Source (ACS). According to some implementations, the drain of each NAND memory string 608 is coupled to a respective bit line 616, and data may be read from or written to the respective bit line 616 via an output bus (not shown). In some implementations, each NAND memory string 608 is configured to be selected or unselected by applying a select voltage or an unselect voltage to a gate of the respective DSG transistor 612 via one or more DSG lines 613 and/or by applying a select voltage or an unselect voltage to a gate of the respective SSG transistor 610 via one or more SSG lines 615.

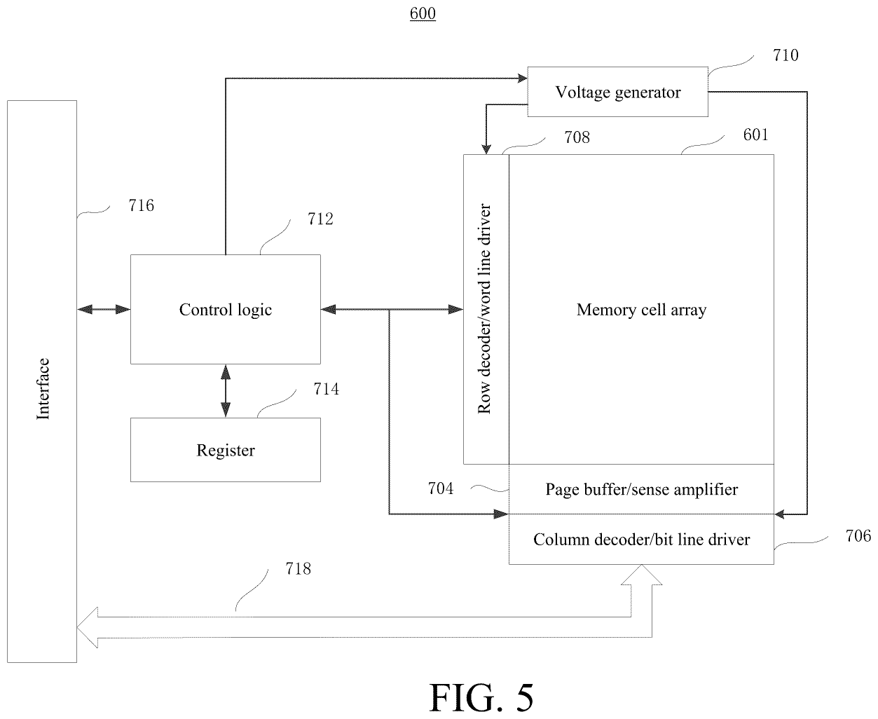

As shown in FIG. 4, the memory strings 608 may be organized into a plurality of blocks 604, and each of the blocks 604 may have, for example, a common source line 614 coupled to the ACS. In some implementations, each block 604 is a basic data unit for an erase operation, that is, all the memory cells 606 on the same block 604 are erased at the same time. In order to erase the memory cells 606 in the selected block 604, the source line 614 coupled to the selected block 604 as well as unselected blocks 604 that are in the same plane as the selected block 604 may be biased with an erase voltage (Vers), such as a high positive bias voltage (e.g., 20 V or higher). The memory cells 606 of adjacent NAND memory strings 608 may be coupled through a Word Line (WL) 618, and the selection of which row of memory cells 606 by Word Line 618 is affected by read and program operations. The peripheral circuit 602 may be coupled to the memory cell array 601 through the Bit Line (BL) 616, the word line 618, the source line 614, the SSG line 615, and the DSG line 613. The peripheral circuit 602 may include any suitable analog, digital, and hybrid signal circuits for facilitating operations of the memory cell array 601 by applying and sensing voltage signals and/or current signals to and from each target memory cell 606 via the bit line 616, the word line 618, the source line 614, the SSG line 615, and the DSG line 613. The peripheral circuit 602 may include various types of peripheral circuits formed using a metal-oxide-semiconductor (MOS) technology. For example, FIG. 5 illustrates some example peripheral circuits, each comprising a page buffer/sense amplifier 704, a column decoder/bit line driver 706, a row decoder/word line driver 708, a voltage generator 710, a control logic 712, a register 714, an interface (I/F) 716, and a data bus 718. It is to be understood that additional peripheral circuits not shown in FIG. 5 may be included as well.

The page buffer/sense amplifier 704 may be configured to read and program (write) data from and to the memory cell array 601 according to a control signal from the control logic 712. In one example, the page buffer/sense amplifier 704 may perform a program verify operation to ensure that data has been properly programmed into the memory cells 606 coupled to the selected word line 618. In another example, during the read operation, the page buffer/sense amplifier 704 may also sense low power signals from the bit line 616 that represent data bits stored in the memory cells 606, and amplify a small voltage swing to a recognizable logic level. As detailed below in consistency with the scope of the present disclosure, in the program operation, the page buffer/sense amplifier 704 may comprise a storage module (e.g., a latch, a cache, a register, etc.) configured to temporarily store a piece of N-bit data (e.g., in the form of a Gray code) received from the data bus 718 and provide the piece of N-bit data to the corresponding target memory cells 606 via the corresponding bit line 616 in each program time of a multi-time program operation using a 2^{N}-2^{N} solution.

The column decoder/bit line driver 706 may be configured to be controlled by the control logic 712 and select one or more NAND memory strings 608 by applying a bit line voltage generated from the voltage generator 710. The row decoder/word line driver 708 may be configured to be controlled by the control logic 712, select/unselect the block 604 of the memory cell array 601, and select/unselect the word line 618 of the block 604. The row decoder/word line driver 708 may be further configured to drive the word line 618 using a word line voltage generated from the voltage generator 710. In some implementations, the row decoder/word line driver 708 may also select/unselect and drive the SSG line 615 and the DSG line 613. The voltage generator 710 may be configured to be controlled by the control logic 712 and generate a word line voltage (such as a read voltage, a program voltage, a pass voltage, a local voltage, or a verify voltage), a bit line voltage, and a source line voltage to be supplied to the memory cell array 601.

The control logic 712 may be coupled to each peripheral circuit described above and configured to control operations of each peripheral circuit. The register 714 may be coupled to the control logic 712 and comprise a state register, a command register, and an address register for storing state information, a command Operation Code (OP), and a command address for controlling the operations of each peripheral circuit. The interface 716 may be coupled to the control logic 712 and act as a control buffer to buffer and forward a control command received from the host (e.g., the host 2000 in FIG. 1) to the control logic 712 and buffer and forward state information received from the control logic 712 to the host. The interface 716 may also be coupled to the column decoder/bit line driver 706 via the data bus 718 and act as a data input/output (I/O) interface and a data buffer to buffer and forward data to and from the memory cell array 601.

With the shrinking of the size of the memory 100 and the wide application of multi-bit storage and 3D stack technologies, these memories 100 gradually become the mainstream storage media because of the advantages such as a large capacity and a high density thereof. However, in a new flash process and organization architecture, although the memory 100 achieves the large storage capacity and high storage density, the problem of internal noise becomes increasingly prominent day by day. A flash channel is restricted by a program/erase count and affected by various factors, such as data retention time and properties of a storage layer, causing a threshold voltage distribution to drift, resulting in an intersection and an overlap between voltage distributions of adjacent states. Such phenomenon leads to the possibility of a flip error during both data write and read processes, which causes the problem in the reliability of data storage. As the flash technology continues to be updated and channel disturbance patterns become increasingly complex day by day, the challenge in the reliability of data storage becomes increasingly large.

In order to improve the reliability of data storage, in some possible implementations, the controller 200 is configured to receive to-be-encoded data (which may also be referred to as to-be-stored data), wherein the to-be-encoded data comprises a plurality of information bits, and different pieces of to-be-encoded data have different numbers of information bits. For example, the to-be-encoded data may comprise N or K information bits, and K<N. A check code vector of the to-be-encoded data is acquired based on the to-be-encoded data, wherein the check code vector is used for an accuracy check of the corresponding to-be-encoded data, and the check code vector comprises a plurality of check bits. An encoded codeword is stored into the memory 100, wherein each encoded codeword comprises the to-be-encoded data and the check code vector corresponding to the to-be-encoded data, and different encoded codewords corresponding to the to-be-encoded data with different numbers of information bits have different numbers of information bits. In a subsequent read of the stored data, the controller 200 reads to-be-decoded data from the memory 100, wherein the to-be-decoded data comprises information bits and check bits, and different pieces of to-be-decoded data have the same number of check bits and the same number or different numbers of information bits. The accuracy of the stored data is verified based on the check bits in the to-be-decoded data, so as to acquire decoded data corresponding to the information bits of the to-be-decoded data.

In the examples of the present disclosure, the accuracy of the to-be-decoded data is verified through the check bits, thereby ensuring the reliability of data storage. Meanwhile, the implementation is applicable to the technical field of communications and the technical field of data storage.

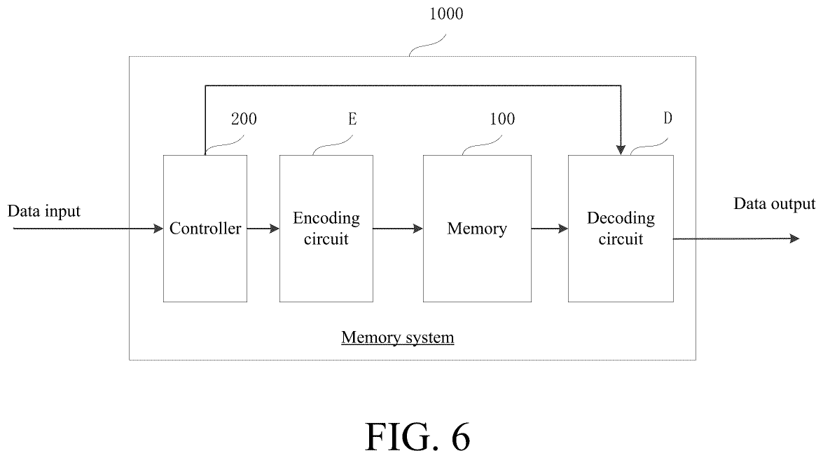

In some possible implementations, taking that the memory system 1000 is applied to the technical field of data storage as an example, as shown in FIG. 6, the memory system 1000 further comprises an encoding circuit E and a decoding circuit D, wherein the encoding circuit E and the decoding circuit D are controlled by the controller 200. Error data is detected and corrected through the encoding circuit E and the decoding circuit D, so as to ensure the correctness of the data stored into the memory system 1000. When there is to-be-stored data written to the memory system 1000, the encoding circuit E first encodes the to-be-stored data to obtain a check code vector, generates an encoded codeword based on the check code vector and the to-be-stored data, and stores the encoded codeword in the memory 100. During a read of the data from the memory system 1000, the data is transferred into the flash channel via a read operation of the memory system 1000, and the to-be-decoded data output from the channel is sent to the decoding circuit D; the decoding circuit D detects an error in the to-be-decoded data and corrects the error within the scope of an error correction capability thereof, finally acquiring and outputting the decoded data.

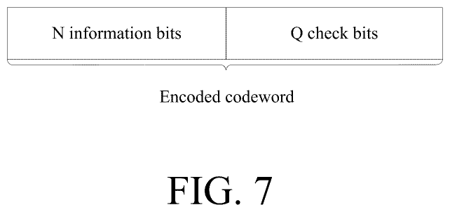

In some examples, the memory system 1000 shown in FIG. 6 may adopt a Low-Density Parity-Check Code (LDPC) technology for error correction of the stored data. The LDPC is a linear block code that is widely applied in communication and storage systems for correcting errors that occur during transmission. It belongs to channel encoding and has an error correction capability that is very close to a theoretical maximum, i.e., Shannon Limit. A principle of LDPC encoding is mainly that the encoding circuit E encodes the to-be-encoded data through a generator matrix M and the decoding circuit D decodes the to-be-decoded data through a check matrix H. The generator matrix M may be selected from a first generator matrix M1 and a second generator matrix M2 according to different application scenarios. In some scenarios of sufficient storage spaces, the first generator matrix M1 may be employed. In other scenarios of limited storage spaces, the second generator matrix M2 may be employed. In an example implementation, the first generator matrix M1 may be a Q×N (Q-row N-column) matrix or Q×(N+Q) (Q-row (N+Q)-column) matrix, wherein Q corresponds to the number of bits of the check code vector, and N columns correspond to N sets of encoding vectors. The check matrix H may be a Q×(N+Q) (Q-row (N+Q)-column) matrix. During an encoding process, the to-be-encoded data is multiplied by the first generator matrix M1 to obtain a set of check code vector. During a decoding process, the received to-be-decoded data is multiplied by the check matrix H to obtain a set of syndrome vector, and the error data is corrected according to the syndrome vector. For example, the to-be-encoded data s comprising N information bits may be extended into the encoded codeword C(s) of N+Q bits via the encoding circuit E, that is, a redundant information code (also referred as check code or check code vector) of Q bits is inserted into the to-be-encoded data s. As shown in FIG. 7, the encoded codeword C(s) comprises N information bits and Q check bits. A data transmitting side uses the redundant information code in the encoded codeword to enable a receiving side to detect and correct the errors that occur during the data transmission, causing the data to have self-check and self-correction abilities, and thereby increasing the reliability of data storage.

In some scenarios, the first generator matrix M1 may be a Q×N (Q-row N-column) matrix. The to-be-encoded data s may comprise N information bits, and the N sets of encoding vectors are in one-to-one correspondence with the N information bits.

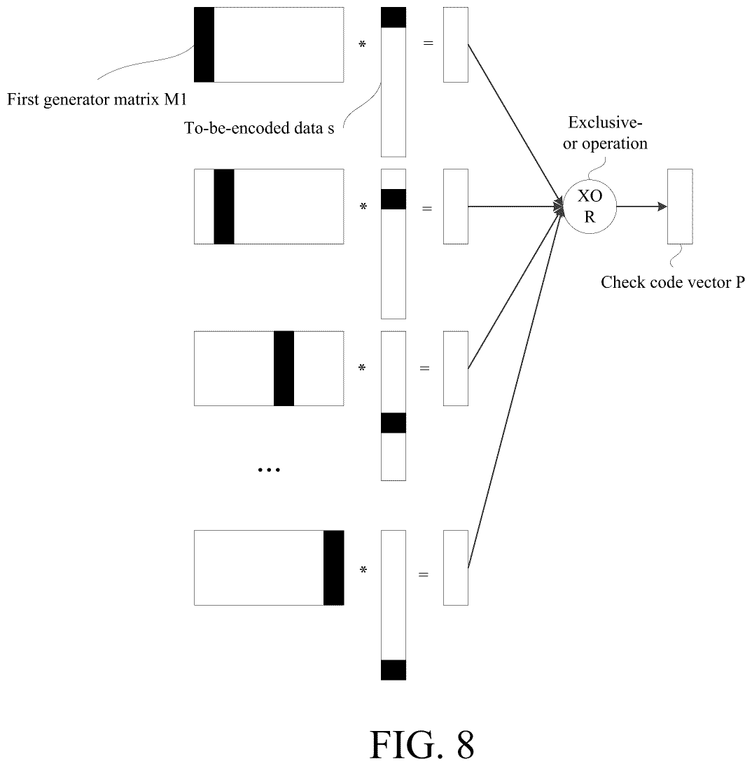

In an example, the first generator matrix M1 may encode the to-be-encoded data comprising the N information bits. An example LDPC encoding process is as shown in FIG. 8, with the check code vector P=M1s. The encoding circuit E performs a matrix multiplication operation on the N information bits of the to-be-encoded data s based on the N sets of encoding vectors in the first generator matrix M1 in a one-to-one correspondence manner, so as to obtain N sets of check code sub-vectors. A bitwise exclusive-or operation is performed on the N sets of check code sub-vectors P, so as to obtain the check code vector P of Q bits, wherein the check code vector P is used for an accuracy check of the to-be-encoded data s. XOR in FIG. 8 denotes the exclusive-or operation (in LDPC encoding and decoding processes, an addition between elements is an exclusive-or operation, that is, an exclusive-or operation between identical elements results in 0, and an exclusive-or operation between different elements results in 1). In this example, the exclusive-or operation may also be denoted by ⊕.

Specifically, taking the to-be-encoded data s=(c₁ c₂ c₃) and the first generator matrix

$$M 1 = ( \begin{matrix}{I}_{11} & {I}_{12} & {I}_{13} \\ {I}_{21} & {I}_{22} & {I}_{23} \\ {I}_{31} & {I}_{32} & {I}_{33}\end{matrix} )$$

as an example, according to formula (1):

$$P = ( \begin{matrix}{P}_{1} \\ {P}_{2} \\ {P}_{3}\end{matrix} ) = ( \begin{matrix}{I}_{11} & {I}_{12} & {I}_{13} \\ {I}_{21} & {I}_{22} & {I}_{23} \\ {I}_{31} & {I}_{32} & {I}_{33}\end{matrix} ) ( \begin{matrix}{c}_{1} \\ {c}_{2} \\ {c}_{3}\end{matrix} ) = ( \begin{matrix}{I}_{11} \\ {I}_{21} \\ {I}_{31}\end{matrix} ) {c}_{1} ⊕ ( \begin{matrix}{I}_{12} \\ {I}_{22} \\ {I}_{32}\end{matrix} ) {c}_{2} ⊕ ( \begin{matrix}{I}_{13} \\ {I}_{23} \\ {I}_{33}\end{matrix} ) {c}_{3} \qquad ( 1 )$$

first, the check code vector P=(P₁ P₂ P₃) may be obtained.

Second, the encoded codeword C(s)=(c₁ c₂ c₃ P₁ P₂ P₃) is generated according to the check code vector P and the to-be-stored data s.

In the encoding process provided in this example, the to-be-encoded data s is multiplied directly by the first generator matrix M1, so as to obtain the check code vector P directly. However, since the Q×N (Q-row N-column) first generator matrix M1 is typically not a sparse matrix, a storage amount and encoding complexity of the generator matrix M are increased.

In order to reduce the storage amount and encoding complexity of the generator matrix M, the second generator matrix M2 may be employed in some other scenarios of limited storage spaces. The second generator matrix M2 may employ an Approximate Lower Triangular encoding manner. In an example implementation, in the approximate lower triangular encoding manner, the second generator matrix M2 may be a Q×(N+Q) (Q-row (N+Q)-column) matrix, wherein Q also denotes the number of bits of the check code vector P, (N+Q) columns correspond to N+Q sets of encoding vectors, and N sets of encoding vectors in the N+Q sets of encoding vectors are in one-to-one correspondence with N information bits. The Q×(N+Q) matrix may be divided into a Q×N matrix portion and a Q×Q matrix portion. The Q×N matrix portion is a sparse matrix, i.e., with less Is and more 0s, in which case only the Is in the matrix may be stored while the remainder of the matrix is 0 by default, thereby reducing a storage amount and encoding complexity of the second generator matrix M2. The Q×Q matrix portion may be an approximate lower triangular matrix, thereby further reducing the storage amount and encoding complexity of the second generator matrix M2. In encoding the to-be-encoded data s comprising the N information bits, the encoding circuit E performs a matrix multiplication operation on the N information bits of the to-be-encoded data s based on the N sets of encoding vectors in the second generator matrix M2 in a one-to-one correspondence manner, so as to obtain N sets of check code sub-vectors, wherein each set of check code sub-vector comprises Q bits. A bitwise exclusive-or operation is performed on the N sets of check code sub-vectors, so as to obtain an intermediate vector of Q bits (data generated during the operation). The intermediate vector of Q bits is multiplied by Q sets of encoding vectors in the second generator matrix M2, so as to obtain the check code vector P, wherein the check code vector P is used for an accuracy check of the to-be-encoded data s.

A principle of performing the accuracy check of the to-be-encoded data s based on the check code vector P may be further explained through the following example: taking the to-be-encoded data s=(1 1 0) and the first generator matrix

$$M 1 = ( \begin{matrix}1 & 1 & 0 \\ 0 & 1 & 1 \\ 1 & 1 & 1\end{matrix} )$$

as an example, P=(0 1 0) may be obtained according to formula (1), and then C(s)=(1 1 0 0 1 0). From formula (1), it can be seen that the check bits P₁, P₂, P₃ have the following relationships, as denoted by formulas (2), (3), and (4):

$${P}_{1} = c 1 ⊕ c 2 \qquad ( 2 )$$

$${P}_{2} = c 2 ⊕ c 3 \qquad ( 3 )$$

$${P}_{3} = c 1 ⊕ c 2 ⊕ c 3 \qquad ( 4 )$$

Formulas (2), (3), and (4) may be converted into formulas (5), (6), and (7):

$$c 1 ⊕ c 2 ⊕ {P}_{1} = 0 \qquad ( 5 )$$

$$c 2 ⊕ c 3 ⊕ {P}_{2} = 0 \qquad ( 6 )$$

$$c 1 ⊕ c 2 ⊕ c 3 ⊕ {P}_{3} = 0 \qquad ( 7 )$$

Formulas (5), (6), and (7) are written in the form of a matrix multiplication as denoted by formula (8):

$$( \begin{matrix}1 & 1 & 0 & 1 & 0 & 0 \\ 0 & 1 & 1 & 0 & 1 & 0 \\ 1 & 1 & 1 & 0 & 0 & 1\end{matrix} ) ( \begin{matrix}{c}_{1} \\ {c}_{2} \\ {c}_{3} \\ {P}_{1} \\ {P}_{2} \\ {P}_{3}\end{matrix} ) = ( \begin{matrix}0 \\ 0 \\ 0\end{matrix} ) \qquad ( 8 )$$

Formula (8) may be denoted as HC^{T}(s)=0, which may also be referred to as a syndrome or syndrome vector, wherein H is the check matrix. As denoted by formula (9), the check matrix H in formula (8) is:

$$H = ( \begin{matrix}1 & 1 & 0 & 1 & 0 & 0 \\ 0 & 1 & 1 & 0 & 1 & 0 \\ 1 & 1 & 1 & 0 & 0 & 1\end{matrix} ) \qquad ( 9 )$$

It can be seen that during the LDPC error correction process, only when the to-be-decoded data output by the flash channel satisfies that the syndrome vector obtained by multiplying the to-be-decoded data by the check matrix H is a zero vector, it indicates that the data is stored correctly. Accordingly, a receiving end may determine whether there is an error in data transmission through the check matrix H.

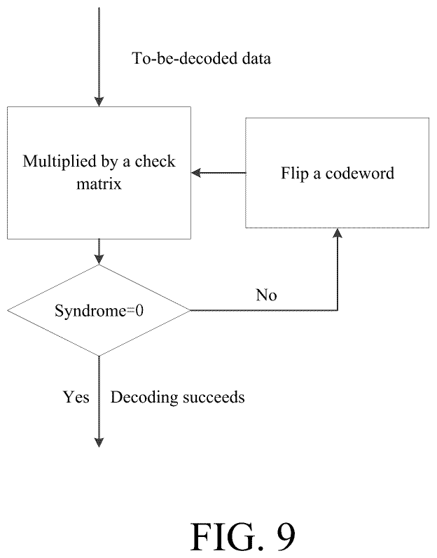

Further, as shown in FIG. 9, error data in the transmission is corrected through the check matrix H, which specifically comprises the following:

First, the to-be-decoded data is multiplied by the check matrix H, so as to obtain the check code vector P. If the syndrome vector is 0, it represents that the decoding succeeds.

Second, if the syndrome vector is not 0, a possible error codeword is detected and flipped, until the syndrome is 0, and then a decoded codeword is output.

If the syndrome vector results in following results:

$$c 1 ⊕ c 2 ⊕ {P}_{1} \neq 0 \qquad ( 10 )$$

$$c 1 ⊕ c 2 ⊕ c 3 ⊕ {P}_{3} \neq 0 \qquad ( 11 )$$

$$c 2 ⊕ c 3 ⊕ {P}_{2} = 0 \qquad ( 6 )$$

First of all, if the relationships denoted by formulas (10) and (11) do not meet a check requirement denoted by formula (8), then it may be determined that there is an error in data storage. An error code bit may be either c1 or c2 (assuming that there is only one error code bit), because a variable that can cause errors in both of the check formulas is necessarily a variable involved in both of the formulas.

Secondly, the case of an error in c2 may be excluded according to c2⊕c3 ⊕P₂=0, and accordingly, the following judgement may be performed: there is an error in c1. At this time, error correction of the error data may be realized just by flipping c1 for output.

In some other scenarios, the first generator matrix M1 may be a Q×N (Q-row N-column) matrix. The to-be-encoded data s may comprise K information bits, and K<N. For example, this example provides two implementations for encoding the to-be-encoded data s: one is to perform a zero filling operation on the to-be-encoded data s, wherein the to-be-encoded data is caused to be aligned with the N sets of encoding vectors of the first generator matrix M1 by filling with N−K (N minus K) 0s, and then encoded. The other is to encode the to-be-encoded data s directly without zero filling.

In an implementation, in some LDPC application scenarios, a data length of the to-be-encoded data s is generally less than or equal to an information bit length of the LDPC employed currently. When there is no corresponding LDPC with an information bit length the same as the data length of the to-be-encoded data s, an LDPC with a slightly larger information bit length is used, and the data length of the to-be-encoded data s is caused to be the same as the information bit length of the LDPC through zero filling, so that the number of bits of the to-be-encoded data s is aligned with the information bits of the LDPC.

Furthermore, if the to-be-encoded data s=(c1 c₂) comprises two information bits c1, c₂, the LDPC encoded codeword is C(s)=(c1 c₂ c₃ P₁ P₂ P₃), wherein c1, c₂, c₃ are information bits, and P₁, P₂, P₃ are check bits. In order to align information bits of the to-be-encoded data s=(c1 c2) and the encoded codeword C(s), it is required to fill the to-be-encoded data s with one 0 as an information bit, wherein the 0 may be filled at the start end of the to-be-encoded data s, e.g., s=(0 c1 c2). 0 may be filled at the tail end of the to-be-encoded data s, e.g., s=(c1 c2 0). 0 may also be filled in the middle of the to-be-encoded data s, e.g., s=(c1 0 c2). Here, taking that 0 is filled at the tail end of the to-be-encoded data s, e.g., s=(c1 c2 0), as an example, s=(c1 c2 0) is fed into the encoding circuit E for processing. The encoding may be performed particularly through formula (1). However, feeding the zero-filled to-be-encoded data s into the encoding circuit E and the decoding circuit D for processing may affect throughput capabilities of the encoding circuit E and the decoding circuit D, increasing a latency, increasing power consumption, and reducing a decoding capability. For software computation, processing the zero-filled data increases arithmetic consumption

In order to improve the throughput capabilities of the encoding circuit E and the decoding circuit D of the LDPC hardware, reduce the latency, save the power consumption, enhance the encoding/decoding capability, and improve the computation efficiency of LDPC software, if there is no corresponding LDPC with an information bit length the same as the length of the to-be-encoded data s, an LDPC with a slightly larger information bit length is used for encoding process, and the to-be-encoded data s is encoded directly without performing zero filling for the to-be-encoded data s.

Specifically, the encoding process comprises: performing a matrix multiplication operation on the K information bits of the to-be-encoded data s based on K sets of target encoding vectors in the first generator matrix M1 in a one-to-one correspondence manner, so as to obtain K sets of check code sub-vectors, and performing a bitwise exclusive-or operation on the K sets of check code sub-vectors, so as to obtain the check code vector P, wherein the check code vector P is used for an accuracy check of the first to-be-encoded data.

Furthermore, taking the to-be-encoded data s=(c₁ c₂) and the first generator matrix

$$M 1 = ( \begin{matrix}{I}_{11} & {I}_{12} & {I}_{13} \\ {I}_{21} & {I}_{22} & {I}_{23} \\ {I}_{31} & {I}_{32} & {I}_{33}\end{matrix} )$$

as an example, the following may be obtained according to formula (1):

$$P = ( \begin{matrix}{P}_{1} \\ {P}_{2} \\ {P}_{3}\end{matrix} ) = ( \begin{matrix}{I}_{11} & {I}_{12} & {I}_{13} \\ {I}_{21} & {I}_{22} & {I}_{23} \\ {I}_{31} & {I}_{32} & {I}_{33}\end{matrix} ) ( \begin{matrix}{c}_{1} \\ {c}_{2}\end{matrix} )$$

$${P}_{1} = ( {c}_{1} \times {I}_{11} ) ⊕ ( {c}_{2} \times {I}_{12} ) , {P}_{2} = ( {c}_{1} \times {I}_{21} ) ⊕ ( {c}_{2} \times {I}_{22} ) , {P}_{3} = ( {c}_{1} \times {I}_{31} ) ⊕ ( {c}_{2} \times {I}_{32} ) ,$$

when it is detected that a column of the first generator matrix M1 do not have a corresponding bit of the to-be-encoded data s, an operation of the current column is skipped, i.e., a third column in the first generator matrix M1 does not participate in the matrix operation. The encoded codeword C(s)=(c1 c₂ σP₁ P₂ P₃) is obtained.

Furthermore, taking the to-be-encoded data s=(1 1) and the first generator matrix

$$M 1 = ( \begin{matrix}1 & 1 & 0 \\ 0 & 1 & 1 \\ 1 & 1 & 1\end{matrix} )$$

as an example, the following operation is performed through formula (1):

$$P = ( \begin{matrix}{P}_{1} \\ {P}_{2} \\ {P}_{3}\end{matrix} ) = ( \begin{matrix}1 & 1 & 0 \\ 0 & 1 & 1 \\ 1 & 1 & 1\end{matrix} ) ( \begin{matrix}1 \\ 1\end{matrix} )$$

The following may be obtained:

$$P = ( \begin{matrix}{P}_{1} \\ {P}_{2} \\ {P}_{3}\end{matrix} ) = 1 \times ( \begin{matrix}1 \\ 0 \\ 1\end{matrix} ) ⊕ 1 \times ( \begin{matrix}1 \\ 1 \\ 1\end{matrix} )$$

$${P}_{1} = ( 1 \times 1 ) ⊕ ( 1 \times 1 ) = 0 , {P}_{2} = ( 1 \times 0 ) ⊕ ( 1 \times 1 ) = 1 , {P}_{3} = ( 1 \times 1 ) ⊕ ( 1 \times 1 ) = 0 , and P = ( \begin{matrix}0 & 1 & 0\end{matrix} ) .$$

Therefore, ignoring non-aligned bits in the to-be-encoded data s, multiplying the bits by corresponding columns of the first generator matrix M1 without zero filling does not affect the final result P.

Similarly, in decoding the encoded codeword, as denoted by formula (8), with the check matrix H denoted by formula (9) as an example, the following may be obtained:

$$( \begin{matrix}1 & 1 & 0 & 1 & 0 & 0 \\ 0 & 1 & 1 & 0 & 1 & 0 \\ 1 & 1 & 1 & 0 & 0 & 1\end{matrix} ) ( \begin{matrix}1 \\ 1 \\ σ \\ 0 \\ 1 \\ 0\end{matrix} ) = ( \begin{matrix}0 \\ 0 \\ 0\end{matrix} )$$

Therefore, performing the matrix operation on the encoded codeword C(s) with the check matrix H by ignoring the non-aligned bits in the encoded codeword C(s) of the to-be-encoded data s and multiplying the bits by the corresponding columns of the check matrix H without zero filling does not affect a final syndrome result. Meanwhile, the risk an erroneous flip of zero filling bits caused by the zero filling for the non-aligned bits may be avoided, achieving fast decoding convergence, and even avoiding a decoding failure to a certain extent.

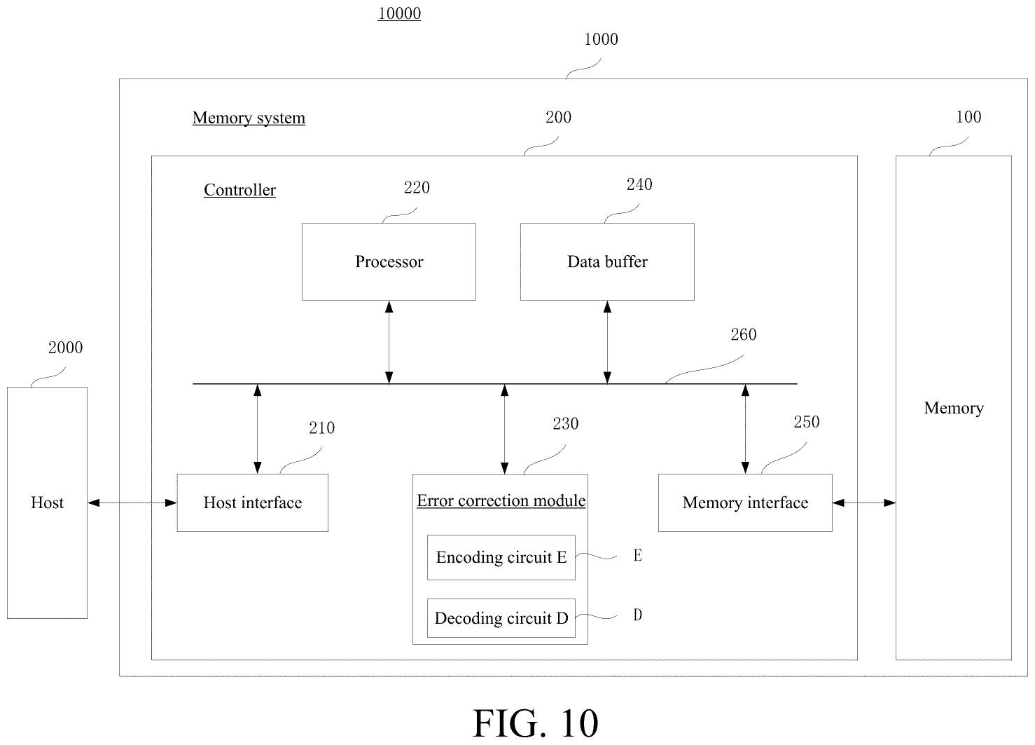

In some examples, in some application scenarios, the encoding circuit E and the decoding circuit D may be integrated in the controller 200, so as to improve the level of integration of the memory system and further miniaturize the memory system. In the electronic device 10000 shown in FIG. 10, the controller 200 comprises a host interface 210, a processor 220, an error correction module 230, a data buffer 240, a memory interface 250, and a connection bus 260, wherein the error correction module 230 comprises the encoding circuit E and the decoding circuit D. In an example implementation, the electronic device 10000 is a complex device that integrates the memory system 1000 and the host 2000. The memory system 1000 is responsible for storage and retrieval of data, while the controller 200 plays a central role in coordinating and managing these operations. Modules within the controller 200 realize high-speed and reliable data transmission and command communication through the connection bus 260. The host interface 210 serves as a bridge to the external host 2000 and is connected with the processor 220 via the connection bus 260 and responsible for receiving and sending data, commands, and status information. The processor 220 is the brain of the controller 200, which parses commands from the host 2000 and coordinates other modules to perform respective operations.

During a data write process, the processor 220 commands the encoding circuitry E in the error correction module 230 to encode raw data. The encoding circuit E receives the data sent by the processor 220, encodes it by adding an ECC check code, etc., and then sends the encoded data to the data buffer 240 via the connection bus 260 for temporary storage. The data buffer 240 serves as a temporary storage region to ensure security and stability of the data before it is written to the memory 100.

When it is required to read the data, the processor 220 sends a read command and an address to the memory 100 via the memory interface 250. After reading the data at the designated address, the memory 100 returns the data to the controller 200 through the memory interface 250. The data first enters the data buffer 240 and then is decoded and subjected to error detection by the decoding circuit D in the error correction module 230. If there is no error in the data, the decoding circuit D transmits the data to the processor 220 via the connection bus 260; if an error is detected, the decoding circuit D notifies the processor 220, so that the processor 220 decides whether to retry a read or report the error to the host 2000.

During the entire process, the processor 220 is also responsible for error handling and status reporting. If the decoding circuit D detects an error, the processor 220 takes an appropriate measure according to the type of the error, such as retrying a read, reporting the error to the host, or performing other error handling processes. Meanwhile, the controller 200 may also report information such as a status of the memory or an error count to the host 2000 via the host interface 210, so that the host 2000 can know an operational condition of the memory system in a timely manner. The memory system 1000 in the electronic device 10000 realizes efficient and stable storage and retrieval of data through cooperative work of the modules within the controller 200. The presence of the connection bus 260 ensures high-speed data transmission and command communication between the modules, enabling the entire system to operate stably and efficiently.

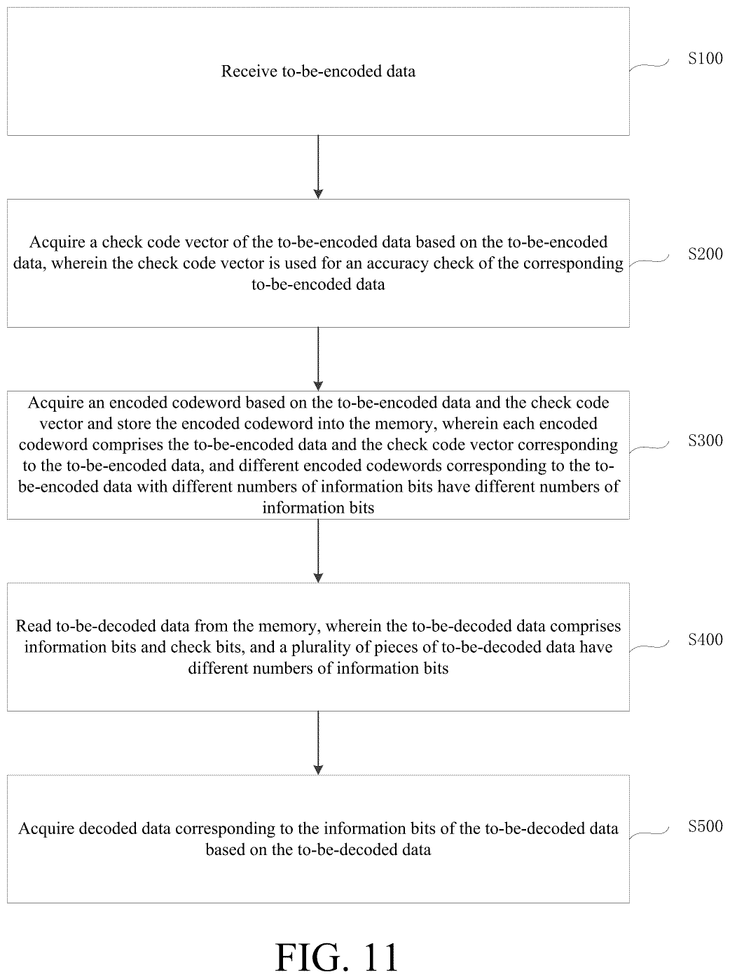

Based on the above device or system shown in FIG. 1, FIG. 2, FIG. 3, FIG. 4, FIG. 5, FIG. 6, and FIG. 10, a method of operating a memory system as shown in FIG. 11 comprising operations S100-S500 below can be realized, the operations including:

S100. To-be-encoded data is received.

In some examples, number of information bits of different pieces of to-be-encoded data may be the same or different.

S200. A check code vector of the to-be-encoded data is acquired based on the to-be-encoded data, wherein the check code vector is used for an accuracy check of the corresponding to-be-encoded data.

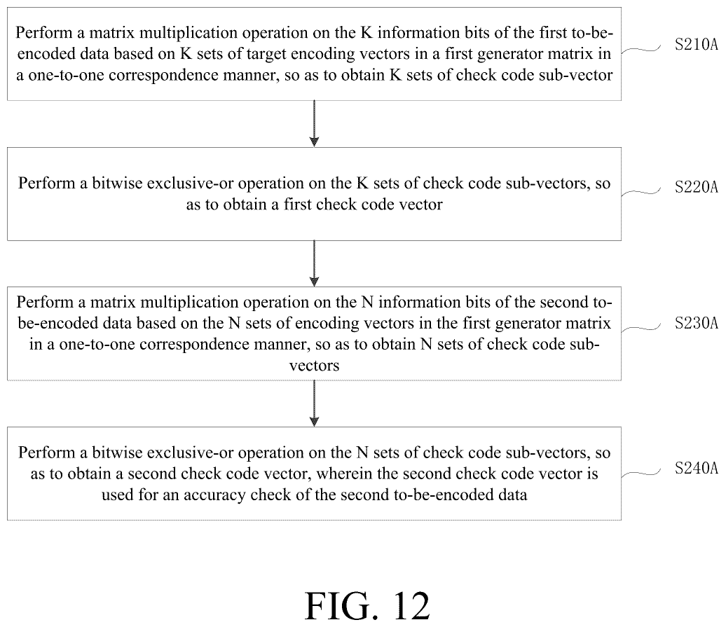

In some examples, the first generator matrix M1 is included in the device or system as shown in FIG. 1, FIG. 2, FIG. 3, FIG. 4, FIG. 5, FIG. 6, and FIG. 10. The first generator matrix M1 may be a Q×N (Q-row N-column) matrix comprising N sets of encoding vectors that may encode the to-be-encoded data comprising N information bits, wherein the N sets of encoding vectors are in one-to-one correspondence with the N information bits. When the number of information bits of the to-be-encoded data is less than or equal to N, as shown in FIG. 12, operation S200 may comprise operations S210A-S240A:

S210A. A matrix multiplication operation is performed on the K information bits of the first to-be-encoded data based on K sets of target encoding vectors in a first generator matrix in a one-to-one correspondence manner, so as to obtain K sets of check code sub-vector.

In an example, the to-be-encoded data comprises first to-be-encoded data, the first to-be-encoded data comprises K information bits, and K<N.

S220A. A bitwise exclusive-or operation is performed on the K sets of check code sub-vectors, so as to obtain a first check code vector.

In an example, in the device or system as shown in FIG. 1, FIG. 2, FIG. 3, FIG. 4, FIG. 5, FIG. 6, and FIG. 10, the matrix multiplication operation is performed on the K information bits of the first to-be-encoded data based on the K sets of target encoding vectors in a first generator matrix M1 in a one-to-one correspondence manner, so as to obtain the K sets of check code sub-vectors. The K sets of target encoding vectors are front-located K sets of target encoding vectors among the N sets of target encoding vectors. Alternatively, the K sets of target encoding vectors are rear-located K sets of target encoding vectors among the N sets of target encoding vectors. Alternatively, the K sets of target encoding vectors are non-consecutively located K sets of target encoding vectors among the N sets of target encoding vectors.

S230A. A matrix multiplication operation is performed on the N information bits of the second to-be-encoded data based on the N sets of encoding vectors in the first generator matrix in a one-to-one correspondence manner, so as to obtain N sets of check code sub-vectors.

In an example, the to-be-encoded data comprises second to-be-encoded data, and the second to-be-encoded data comprises N information bits.

S240A. A bitwise exclusive-or operation is performed on the N sets of check code sub-vectors, so as to obtain a second check code vector, wherein the second check code vector is used for an accuracy check of the second to-be-encoded data.

In an example, in the device or system as shown in FIG. 1, FIG. 2, FIG. 3, FIG. 4, FIG. 5, FIG. 6, and FIG. 10, the matrix multiplication operation is performed on the N information bits of the second to-be-encoded data based on the N sets of encoding vectors in the first generator matrix M1 in a one-to-one correspondence manner, so as to obtain the N sets of check code sub-vectors. A bitwise exclusive-or operation is performed on the N sets of check code sub-vectors, so as to obtain a second check code vector, wherein the second check code vector may be used for an accuracy check of the second to-be-encoded data.

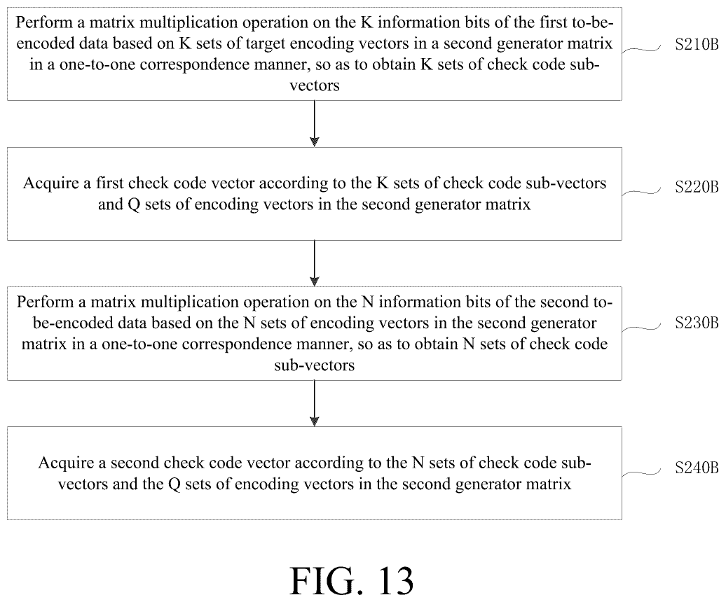

In some examples, the second generator matrix M2 may be included in the device or system as shown in FIG. 1, FIG. 2, FIG. 3, FIG. 4, FIG. 5, FIG. 6, and FIG. 10. The second generator matrix may be a Q×(N+Q) (Q-row (N+Q) column) matrix, wherein Q also denotes the number of bits of the check code vector, (N+Q) columns correspond to N+Q sets of encoding vectors, N sets of encoding vectors in the N+Q sets of encoding vectors are in one-to-one correspondence with the N information bits, the N sets of encoding vectors comprise the K sets of target encoding vectors, and the number of information bits of the to-be-encoded data is less than or equal to N. As shown in FIG. 13, operation S200 may comprise operations S210B-S240B:

S210B. A matrix multiplication operation is performed on the K information bits of the first to-be-encoded data based on K sets of target encoding vectors in a second generator matrix in a one-to-one correspondence manner, so as to obtain K sets of check code sub-vectors.

In an example, the to-be-encoded data comprises first to-be-encoded data, the first to-be-encoded data comprises K information bits, and K<N.

S220B. A first check code vector is acquired according to the K sets of check code sub-vectors and Q sets of encoding vectors in the second generator matrix.

In an example, in the device or system as shown in FIG. 1, FIG. 2, FIG. 3, FIG. 4, FIG. 5, FIG. 6, and FIG. 10, the matrix multiplication operation is performed on the K information bits of the first to-be-encoded data based on the K sets of target encoding vectors in a second generator matrix M2 in a one-to-one correspondence manner, so as to obtain the K sets of check code sub-vectors. A bitwise exclusive-or operation is performed on the K sets of check code sub-vectors, so as to obtain the first check code vector. The first check code vector is used for an accuracy check of the first to-be-encoded data.

S230B. A matrix multiplication operation is performed on the N information bits of the second to-be-encoded data based on the N sets of encoding vectors in the second generator matrix in a one-to-one correspondence manner, so as to obtain N sets of check code sub-vectors.

In an example, the to-be-encoded data may comprise second to-be-encoded data, and the second to-be-encoded data comprises N information bits.

S240B. A second check code vector is acquired according to the N sets of check code sub-vectors and the Q sets of encoding vectors in the second generator matrix.

In an example, the second generator matrix M2 may employ an Approximate Lower Triangular encoding manner. In an example implementation, in the approximate lower triangular encoding manner, the second generator matrix M2 may be a Q×(N+Q) (Q-row (N+Q)-column) matrix, wherein Q also denotes the number of bits of the check code vector P, (N+Q) columns correspond to N+Q sets of encoding vectors, and N sets of encoding vectors in the N+Q sets of encoding vectors are in one-to-one correspondence with N information bits. The Q×(N+Q) matrix may be divided into a Q×N matrix portion and a Q×Q matrix portion. The Q×N matrix portion is a sparse matrix, i.e., with less Is and more 0s, in which case only the Is in the matrix may be stored while the remainder of the matrix is 0 by default, thereby reducing a storage amount and encoding complexity of the second generator matrix M2. The Q×Q matrix portion may be an approximate lower triangular matrix, thereby further reducing the storage amount and encoding complexity of the second generator matrix M2. In encoding the to-be-encoded data s comprising the N information bits, in the device or system as shown in FIG. 6 or FIG. 10, the encoding circuit E performs a matrix multiplication operation on the N information bits of the to-be-encoded data s based on the N sets of encoding vectors in the second generator matrix M2 in a one-to-one correspondence manner, so as to obtain N sets of check code sub-vectors, wherein each set of check code sub-vector comprises Q bits. A bitwise exclusive-or operation is performed on the N sets of check code sub-vectors, so as to obtain an intermediate vector of Q bits (data generated during the operation). The intermediate vector of Q bits is multiplied by Q sets of encoding vectors in the second generator matrix M2, so as to obtain the check code vector P, wherein the check code vector P is used for an accuracy check of the to-be-encoded data s.

S300. An encoded codeword is acquired based on the to-be-encoded data and the check code vector and stored into the memory, wherein each encoded codeword comprises the to-be-encoded data and the check code vector corresponding to the to-be-encoded data, and different encoded codewords corresponding to the to-be-encoded data with different numbers of information bits have different numbers of information bits.

In an example, in the example shown by operation S200, the to-be-encoded data may comprise the first to-be-encoded data and the second to-be-encoded data. The first to-be-encoded data comprises K information bits, and K<N. The second to-be-encoded data comprises N information bits. Accordingly, different encoded codewords corresponding to the to-be-encoded data with different numbers of information bits have different numbers of information bits.

S400. To-be-decoded data is read from the memory, wherein the to-be-decoded data comprises information bits and check bits, and a plurality of pieces of to-be-decoded data have different numbers of information bits.

In an example, in the example shown by operation S200, the to-be-encoded data may comprise the first to-be-encoded data and the second to-be-encoded data. The first to-be-encoded data comprises K information bits, and K<N. The second to-be-encoded data comprises N information bits. Accordingly, different encoded codewords corresponding to the to-be-encoded data with different numbers of information bits have different numbers of information bits. Furthermore, a plurality of pieces of to-be-decoded data have different numbers of information bits.

S500. Decoded data corresponding to the information bits of the to-be-decoded data is acquired based on the to-be-decoded data.

In some examples, the generator matrix H in the device or system as shown in FIG. 1, FIG. 2, FIG. 3, FIG. 4, FIG. 5, FIG. 6, and FIG. 10 may be a Q×(Q+N) (Q-row (Q+N)-column) matrix comprising N+Q sets of decoding vectors that may decode the to-be-decoded data comprising N information bits and Q check bits, wherein the N+Q sets of decoding vectors are in one-to-one correspondence with the N information bits and the Q check bits. The to-be-decoded data comprises first to-be-decoded data, the first to-be-decoded data comprises K information bits and Q check bits, and K<N. A matrix multiplication operation is performed on K+Q bits in the first to-be-decoded data based on K+Q sets of target decoding vectors in the check matrix H in a one-to-one correspondence manner, so as to obtain a syndrome vector of the Q check bits. The syndrome vector is used to correct an error code in the first to-be-decoded data. Decoded data corresponding to the K information bits of the first to-be-decoded data is acquired when the syndrome vector is a zero vector.

In an example, the to-be-decoded data comprises second to-be-decoded data, and the second to-be-decoded data comprises N information bits and Q check bits. A matrix multiplication operation is performed on N+Q bits in the second to-be-decoded data based on the N+Q sets of decoding vectors in the check matrix H in a one-to-one correspondence manner, so as to obtain a syndrome vector of the Q check bits. Decoded data corresponding to the N information bits of the second to-be-decoded data is acquired when the syndrome vector is a zero vector.

Examples of the present disclosure provide a memory system and a method of operating a memory system, without performing zero filling to cause the to-be-encoded data comprising different numbers of information bits to have the same number of bits before encoding, the to-be-encoded data comprising different numbers of information bits is encoded directly, so as to improve the throughput capabilities of the encoding circuit and the decoding circuit of hardware, reduce the latency, save the power consumption, and enhance the encoding/decoding capability. Meanwhile, the computation efficiency is improved.

Examples of the present application further provide a non-transitory, computer readable storage medium comprising instructions. The instructions, when being run on the memory system as described in the above examples, cause the memory system to perform the method of operating a memory system as described in the above examples (such as the method of operating a memory system related to the examples of the device or system shown in FIG. 1, FIG. 2, FIG. 3, FIG. 4, FIG. 5, FIG. 6, and FIG. 10).

Examples of the present disclosure provide a memory system and a method of operating a memory system, so as to improve the reliability of data storage.

In order to achieve the purpose described above, the examples of the present disclosure employ the following technical solutions.

In a first aspect, examples of the present disclosure provide a memory system, comprising: a memory and a controller. The memory is coupled with the controller. The controller is configured to: receive to-be-encoded data; acquire a check code vector of the to-be-encoded data based on the to-be-encoded data, wherein the check code vector is used for an accuracy check of the corresponding to-be-encoded data; and store an encoded codeword into the memory, wherein each encoded codeword comprises the to-be-encoded data and the check code vector corresponding to the to-be-encoded data, and different encoded codewords corresponding to the to-be-encoded data with different numbers of information bits have different numbers of information bits.

In some possible implementations, the number of information bits of the to-be-encoded data is less than or equal to N. The to-be-encoded data comprises first to-be-encoded data, the first to-be-encoded data comprises K information bits, and K<N. The acquiring a check code vector of the to-be-encoded data based on the to-be-encoded data comprises: performing a matrix multiplication operation on the K information bits of the first to-be-encoded data based on K sets of target encoding vectors in a first generator matrix in a one-to-one correspondence manner, so as to obtain K sets of check code sub-vectors, wherein the first generator matrix comprises N sets of encoding vectors, and the N sets of encoding vectors are in one-to-one correspondence with N information bits; and performing a bitwise exclusive-or operation on the K sets of check code sub-vectors, so as to obtain a first check code vector, wherein the first check code vector is used for an accuracy check of the first to-be-encoded data.

In some possible implementations, the to-be-encoded data comprises second to-be-encoded data, and the second to-be-encoded data comprises N information bits. The acquiring a check code vector of the to-be-encoded data based on the to-be-encoded data comprises: performing a matrix multiplication operation on the N information bits of the second to-be-encoded data based on the N sets of encoding vectors in the first generator matrix in a one-to-one correspondence manner, so as to obtain N sets of check code sub-vectors; and performing a bitwise exclusive-or operation on the N sets of check code sub-vectors, so as to obtain a second check code vector, wherein the second check code vector is used for an accuracy check of the second to-be-encoded data.

In some possible implementations, the number of information bits of the to-be-encoded data is less than or equal to N. The to-be-encoded data comprises first to-be-encoded data, the first to-be-encoded data comprises K information bits, and K<N. The acquiring a check code vector of the to-be-encoded data based on the to-be-encoded data comprises: performing a matrix multiplication operation on the K information bits of the first to-be-encoded data based on K sets of target encoding vectors in a second generator matrix in a one-to-one correspondence manner, so as to obtain K sets of check code sub-vectors, wherein the second generator matrix comprises N+Q sets of encoding vectors, N sets of encoding vectors in the N+Q sets of encoding vectors are in one-to-one correspondence with N information bits, and the N sets of encoding vectors comprise the K sets of target encoding vectors; and acquiring a first check code vector according to the K sets of check code sub-vectors and Q sets of encoding vectors in the second generator matrix, wherein the first check code vector is used for an accuracy check of the first to-be-encoded data.

In some possible implementations, the to-be-encoded data comprises second to-be-encoded data, and the second to-be-encoded data comprises N information bits. The acquiring a check code vector of the to-be-encoded data based on the to-be-encoded data comprises: performing a matrix multiplication operation on the N information bits of the second to-be-encoded data based on the N sets of encoding vectors in the second generator matrix in a one-to-one correspondence manner, so as to obtain N sets of check code sub-vectors; and acquiring a second check code vector according to the N sets of check code sub-vectors and the Q sets of encoding vectors in the second generator matrix, wherein the second check code vector is used for an accuracy check of the second to-be-encoded data.

In some possible implementations, the controller is further configured to: read to-be-decoded data from the memory, wherein the to-be-decoded data comprises information bits and check bits, and a plurality of pieces of to-be-decoded data have different numbers of information bits; and acquire decoded data corresponding to the information bits of the to-be-decoded data based on the to-be-decoded data.

In some possible implementations, the number of the information bits in the to-be-decoded data is less than or equal to N, and the number of the check bits is equal to Q. The to-be-decoded data comprises first to-be-decoded data, the first to-be-decoded data comprises K information bits and Q check bits, and K<N. The acquiring decoded data corresponding to the information bits of the to-be-decoded data based on the to-be-decoded data comprises: performing a matrix multiplication operation on K+Q bits in the first to-be-decoded data based on K+Q sets of target decoding vectors in a check matrix in a one-to-one correspondence manner, so as to obtain a syndrome vector of the Q check bits, wherein the check matrix comprises N+Q sets of decoding vectors, the N+Q sets of decoding vectors are in one-to-one correspondence with the N information bits and the Q check bits, and the syndrome vector is used to correct an error code in the first to-be-decoded data; and acquiring decoded data corresponding to the K information bits of the first to-be-decoded data when the syndrome vector is a zero vector.

In some possible implementations, the to-be-decoded data comprises second to-be-decoded data, and the second to-be-decoded data comprises N information bits and Q check bits. The acquiring decoded data corresponding to the information bits of the to-be-decoded data based on the to-be-decoded data comprises: performing a matrix multiplication operation on N+Q bits in the second to-be-decoded data based on the N+Q sets of decoding vectors in the check matrix in a one-to-one correspondence manner, so as to obtain a syndrome vector of the Q check bits; and acquiring decoded data corresponding to the N information bits of the second to-be-decoded data when the syndrome vector is a zero vector.

In a second aspect, examples of the present disclosure provide a memory system, comprising: a memory and a controller. The memory is coupled with the controller. The controller is configured to: read to-be-decoded data from the memory, wherein the to-be-decoded data comprises information bits and check bits, and a plurality of pieces of to-be-decoded data have different numbers of information bits; and acquire decoded data corresponding to the information bits of the to-be-decoded data based on the to-be-decoded data.

In some possible implementations, the number of the information bits in the to-be-decoded data is less than or equal to N, and the number of the check bits is equal to Q. The to-be-decoded data comprises first to-be-decoded data, the first to-be-decoded data comprises K information bits and Q check bits, and K<N. The acquiring decoded data corresponding to the information bits of the to-be-decoded data based on the to-be-decoded data comprises: performing a matrix multiplication operation on K+Q bits in the first to-be-decoded data based on K+Q sets of target decoding vectors in a check matrix in a one-to-one correspondence manner, so as to obtain a syndrome vector of the Q check bits, wherein the check matrix comprises N+Q sets of decoding vectors, the N+Q sets of decoding vectors are in one-to-one correspondence with the N information bits and the Q check bits, and the syndrome vector is used to correct an error code in the first to-be-decoded data; and acquiring decoded data corresponding to the K information bits of the first to-be-decoded data when the syndrome vector is a zero vector.

In some possible implementations, the to-be-decoded data comprises second to-be-decoded data, and the second to-be-decoded data comprises N information bits and Q check bits. The acquiring decoded data corresponding to the information bits of the to-be-decoded data based on the to-be-decoded data comprises: performing a matrix multiplication operation on N+Q bits in the second to-be-decoded data based on the N+Q sets of decoding vectors in the check matrix in a one-to-one correspondence manner, so as to obtain a syndrome vector of the Q check bits; and acquiring decoded data corresponding to the N information bits of the second to-be-decoded data when the syndrome vector is a zero vector.

In a third aspect, examples of the present disclosure provide a method of operating a memory system, wherein the method comprises: receiving to-be-encoded data; acquiring a check code vector of the to-be-encoded data based on the to-be-encoded data, wherein the check code vector is used for an accuracy check of the corresponding to-be-encoded data; and storing an encoded codeword into the memory, wherein each encoded codeword comprises the to-be-encoded data and the check code vector corresponding to the to-be-encoded data, and different encoded codewords corresponding to the to-be-encoded data with different numbers of information bits have different numbers of information bits.

In some possible implementations, the number of information bits of the to-be-encoded data is less than or equal to N. The to-be-encoded data comprises first to-be-encoded data, the first to-be-encoded data comprises K information bits, and K<N. The acquiring a check code vector of the to-be-encoded data based on the to-be-encoded data comprises: performing a matrix multiplication operation on the K information bits of the first to-be-encoded data based on K sets of target encoding vectors in a first generator matrix in a one-to-one correspondence manner, so as to obtain K sets of check code sub-vectors, wherein the first generator matrix comprises N sets of encoding vectors, and the N sets of encoding vectors are in one-to-one correspondence with N information bits; and performing a bitwise exclusive-or operation on the K sets of check code sub-vectors, so as to obtain a first check code vector, wherein the first check code vector is used for an accuracy check of the first to-be-encoded data.

In some possible implementations, the to-be-encoded data comprises second to-be-encoded data, and the second to-be-encoded data comprises N information bits. The acquiring a check code vector of the to-be-encoded data based on the to-be-encoded data comprises: performing a matrix multiplication operation on the N information bits of the second to-be-encoded data based on the N sets of encoding vectors in the first generator matrix in a one-to-one correspondence manner, so as to obtain N sets of check code sub-vectors; and performing a bitwise exclusive-or operation on the N sets of check code sub-vectors, so as to obtain a second check code vector, wherein the second check code vector is used for an accuracy check of the second to-be-encoded data.

In some possible implementations, the number of information bits of the to-be-encoded data is less than or equal to N. The to-be-encoded data comprises first to-be-encoded data, the first to-be-encoded data comprises K information bits, and K<N. The acquiring a check code vector of the to-be-encoded data based on the to-be-encoded data comprises: performing a matrix multiplication operation on the K information bits of the first to-be-encoded data based on K sets of target encoding vectors in a second generator matrix in a one-to-one correspondence manner, so as to obtain K sets of check code sub-vectors, wherein the second generator matrix comprises N+Q sets of encoding vectors, N sets of encoding vectors in the N+Q sets of encoding vectors are in one-to-one correspondence with N information bits, and the N sets of encoding vectors comprise the K sets of target encoding vectors; and acquiring a first check code vector according to the K sets of check code sub-vectors and Q sets of encoding vectors in the second generator matrix, wherein the first check code vector is used for an accuracy check of the first to-be-encoded data.

In some possible implementations, the to-be-encoded data comprises second to-be-encoded data, and the second to-be-encoded data comprises N information bits. The acquiring a check code vector of the to-be-encoded data based on the to-be-encoded data comprises: performing a matrix multiplication operation on the N information bits of the second to-be-encoded data based on the N sets of encoding vectors in the second generator matrix in a one-to-one correspondence manner, so as to obtain N sets of check code sub-vectors; and acquiring a second check code vector according to the N sets of check code sub-vectors and the Q sets of encoding vectors in the second generator matrix, wherein the second check code vector is used for an accuracy check of the second to-be-encoded data.

In some possible implementations, the method further comprises: reading to-be-decoded data from the memory, wherein the to-be-decoded data comprises information bits and check bits, and a plurality of pieces of to-be-decoded data have different numbers of information bits; and acquiring decoded data corresponding to the information bits of the to-be-decoded data based on the to-be-decoded data.

In some possible implementations, the number of the information bits in the to-be-decoded data is less than or equal to N, and the number of the check bits is equal to Q. The to-be-decoded data comprises first to-be-decoded data, the first to-be-decoded data comprises K information bits and Q check bits, and K<N. The acquiring decoded data corresponding to the information bits of the to-be-decoded data based on the to-be-decoded data comprises: performing a matrix multiplication operation on K+Q bits in the first to-be-decoded data based on K+Q sets of target decoding vectors in a check matrix in a one-to-one correspondence manner, so as to obtain a syndrome vector of the Q check bits, wherein the check matrix comprises N+Q sets of decoding vectors, the N+Q sets of decoding vectors are in one-to-one correspondence with the N information bits and the Q check bits, and the syndrome vector is used to correct an error code in the first to-be-decoded data; and acquiring decoded data corresponding to the K information bits of the first to-be-decoded data when the syndrome vector is a zero vector.

In some possible implementations, the to-be-decoded data comprises second to-be-decoded data, and the second to-be-decoded data comprises N information bits and Q check bits. The acquiring decoded data corresponding to the information bits of the to-be-decoded data based on the to-be-decoded data comprises: performing a matrix multiplication operation on N+Q bits in the second to-be-decoded data based on the N+Q sets of decoding vectors in the check matrix in a one-to-one correspondence manner, so as to obtain a syndrome vector of the Q check bits; and acquiring decoded data corresponding to the N information bits of the second to-be-decoded data when the syndrome vector is a zero vector.

In a fourth aspect, examples of the present disclosure provide a method of operating a memory system, wherein the method comprises: reading to-be-decoded data from the memory, wherein the to-be-decoded data comprises information bits and check bits, and a plurality of pieces of to-be-decoded data have different numbers of information bits; and acquiring decoded data corresponding to the information bits of the to-be-decoded data based on the to-be-decoded data.

In some possible implementations, the number of the information bits in the to-be-decoded data is less than or equal to N, and the number of the check bits is equal to Q. The to-be-decoded data comprises first to-be-decoded data, the first to-be-decoded data comprises K information bits and Q check bits, and K<N. The acquiring decoded data corresponding to the information bits of the to-be-decoded data based on the to-be-decoded data comprises: performing a matrix multiplication operation on K+Q bits in the first to-be-decoded data based on K+Q sets of target decoding vectors in a check matrix in a one-to-one correspondence manner, so as to obtain a syndrome vector of the Q check bits, wherein the check matrix comprises N+Q sets of decoding vectors, the N+Q sets of decoding vectors are in one-to-one correspondence with the N information bits and the Q check bits, and the syndrome vector is used to correct an error code in the first to-be-decoded data; and acquiring decoded data corresponding to the K information bits of the first to-be-decoded data when the syndrome vector is a zero vector.

In some possible implementations, the to-be-decoded data comprises second to-be-decoded data, and the second to-be-decoded data comprises N information bits and Q check bits. The acquiring decoded data corresponding to the information bits of the to-be-decoded data based on the to-be-decoded data comprises: performing a matrix multiplication operation on N+Q bits in the second to-be-decoded data based on the N+Q sets of decoding vectors in the check matrix in a one-to-one correspondence manner, so as to obtain a syndrome vector of the Q check bits; and acquiring decoded data corresponding to the N information bits of the second to-be-decoded data when the syndrome vector is a zero vector.

In a fifth aspect, examples of the present disclosure provide a computer readable storage medium, comprising instructions. The instructions, when being run on a processor, cause the processor to perform any one of the method of operating a memory system in the third aspect and/or any one of the method of operating a memory system in the fourth aspect.

The above descriptions are merely particular implementations of the present disclosure, and the protection scope of the present disclosure is not limited to these. Any variation or replacement that may be readily figured out by those skilled in the art within the technical scope disclosed by the present disclosure shall be encompassed within the protection scope of the present disclosure. Therefore, the protection scope of the present disclosure should be defined by the protection scope of the claims.

What is claimed is:

1. A memory system, comprising:
a memory; and
a controller, coupled to the memory and configured to:
receive to-be-encoded data;
acquire a check code vector of the to-be-encoded data based on the to-be-encoded data, wherein the check code vector is used for an accuracy check of corresponding to-be-encoded data; and
store an encoded codeword into the memory, wherein each encoded codeword includes the to-be-encoded data and the check code vector corresponding to the to-be-encoded data, and different encoded codewords corresponding to the to-be-encoded data with different numbers of information bits have different numbers of information bits.

2. The memory system of claim 1, wherein a number of information bits of the to-be-encoded data is less than or equal to N; the to-be-encoded data includes first to-be-encoded data, the first to-be-encoded data includes K information bits, and K<N; and to acquire the check code vector of the to-be-encoded data based on the to-be-encoded data includes to:
perform a matrix multiplication operation on the K information bits of the first to-be-encoded data based on K sets of target encoding vectors in a first generator matrix in a one-to-one correspondence manner, so as to obtain K sets of check code sub-vectors, wherein the first generator matrix comprises N sets of encoding vectors, and the N sets of encoding vectors are in one-to-one correspondence with N information bits; and
perform a bitwise exclusive-or operation on the K sets of check code sub-vectors, so as to obtain a first check code vector, wherein the first check code vector is used for an accuracy check of the first to-be-encoded data.

3. The memory system of claim 2, wherein the to-be-encoded data includes second to-be-encoded data, and the second to-be-encoded data includes N information bits; and to acquire the check code vector of the to-be-encoded data based on the to-be-encoded data includes to:
perform a matrix multiplication operation on the N information bits of the second to-be-encoded data based on the N sets of encoding vectors in the first generator matrix in a one-to-one correspondence manner, so as to obtain N sets of check code sub-vectors; and
perform a bitwise exclusive-or operation on the N sets of check code sub-vectors, so as to obtain a second check code vector, wherein the second check code vector is used for an accuracy check of the second to-be-encoded data.

4. The memory system of claim 1, wherein a number of information bits of the to-be-encoded data is less than or equal to N; the to-be-encoded data includes first to-be-encoded data, the first to-be-encoded data includes K information bits, and K<N; and to acquire the check code vector of the to-be-encoded data based on the to-be-encoded data includes to:
perform a matrix multiplication operation on the K information bits of the first to-be-encoded data based on K sets of target encoding vectors in a second generator matrix in a one-to-one correspondence manner, so as to obtain K sets of check code sub-vectors, wherein the second generator matrix includes N+Q sets of encoding vectors, N sets of encoding vectors in the N+Q sets of encoding vectors are in one-to-one correspondence with N information bits, and the N sets of encoding vectors include the K sets of target encoding vectors; and
acquire a first check code vector according to the K sets of check code sub-vectors and Q sets of encoding vectors in the second generator matrix, wherein the first check code vector is used for an accuracy check of the first to-be-encoded data.

5. The memory system of claim 4, wherein the to-be-encoded data includes second to-be-encoded data, and the second to-be-encoded data includes N information bits; and to acquire the check code vector of the to-be-encoded data based on the to-be-encoded data includes to:
perform a matrix multiplication operation on the N information bits of the second to-be-encoded data based on the N sets of encoding vectors in the second generator matrix in a one-to-one correspondence manner, so as to obtain N sets of check code sub-vectors; and
acquire a second check code vector according to the N sets of check code sub-vectors and the Q sets of encoding vectors in the second generator matrix, wherein the second check code vector is used for an accuracy check of the second to-be-encoded data.

6. The memory system of claim 1, wherein the controller is further configured to:
read to-be-decoded data from the memory, wherein the to-be-decoded data includes information bits and check bits, and a plurality of pieces of to-be-decoded data have different numbers of information bits; and
acquire decoded data corresponding to the information bits of the to-be-decoded data based on the to-be-decoded data.

7. The memory system of claim 6, wherein a number of the information bits in the to-be-decoded data is less than or equal to N, and a number of the check bits is equal to Q; the to-be-decoded data includes first to-be-decoded data, the first to-be-decoded data includes K information bits and Q check bits, and K<N; and to acquire the decoded data corresponding to the information bits of the to-be-decoded data based on the to-be-decoded data includes to:
perform a matrix multiplication operation on K+Q bits in the first to-be-decoded data based on K+Q sets of target decoding vectors in a check matrix in a one-to-one correspondence manner, so as to obtain a syndrome vector of the Q check bits, wherein the check matrix includes N+Q sets of decoding vectors, the N+Q sets of decoding vectors are in one-to-one correspondence with N information bits and the Q check bits, and the syndrome vector is used to correct an error code in the first to-be-decoded data; and
acquire decoded data corresponding to the K information bits of the first to-be-decoded data when the syndrome vector is a zero vector.

8. The memory system of claim 7, wherein the to-be-decoded data includes second to-be-decoded data, and the second to-be-decoded data includes N information bits and Q check bits; and to acquire the decoded data corresponding to the information bits of the to-be-decoded data based on the to-be-decoded data includes to:
perform a matrix multiplication operation on N+Q bits in the second to-be-decoded data based on the N+Q sets of decoding vectors in the check matrix in a one-to-one correspondence manner, so as to obtain a syndrome vector of the Q check bits; and
acquire decoded data corresponding to the N information bits of the second to-be-decoded data when the syndrome vector is a zero vector.

9. The memory system of claim 1, wherein the memory system comprises a solid state drive (SSD).

10. A memory system, comprising:
a memory; and
a controller, coupled to the memory and configured to:
read to-be-decoded data from the memory, wherein the to-be-decoded data includes information bits and check bits, and a plurality of pieces of to-be-decoded data have different numbers of information bits; and
acquire decoded data corresponding to the information bits of the to-be-decoded data based on the to-be-decoded data.

11. The memory system of claim 10, wherein a number of the information bits in the to-be-decoded data is less than or equal to N, and a number of the check bits is equal to Q; the to-be-decoded data includes first to-be-decoded data, the first to-be-decoded data includes K information bits and Q check bits, and K<N; and to acquire the decoded data corresponding to the information bits of the to-be-decoded data based on the to-be-decoded data includes to:
perform a matrix multiplication operation on K+Q bits in the first to-be-decoded data based on K+Q sets of target decoding vectors in a check matrix in a one-to-one correspondence manner, so as to obtain a syndrome vector of the Q check bits, wherein the check matrix includes N+Q sets of decoding vectors, the N+Q sets of decoding vectors are in one-to-one correspondence with N information bits and the Q check bits, and the syndrome vector is used to correct an error code in the first to-be-decoded data; and
acquire decoded data corresponding to the K information bits of the first to-be-decoded data when the syndrome vector is a zero vector.

12. The memory system of claim 11, wherein the to-be-decoded data includes second to-be-decoded data, and the second to-be-decoded data includes N information bits and Q check bits; and to acquire the decoded data corresponding to the information bits of the to-be-decoded data based on the to-be-decoded data includes to:
perform a matrix multiplication operation on N+Q bits in the second to-be-decoded data based on the N+Q sets of decoding vectors in the check matrix in a one-to-one correspondence manner, so as to obtain a syndrome vector of the Q check bits; and
acquire decoded data corresponding to the N information bits of the second to-be-decoded data when the syndrome vector is a zero vector.

13. A method of operating a memory system, comprising:
receiving to-be-encoded data;
acquiring a check code vector of the to-be-encoded data based on the to-be-encoded data, wherein the check code vector is used for an accuracy check of corresponding to-be-encoded data; and
storing an encoded codeword into a memory, wherein each encoded codeword includes the to-be-encoded data and the check code vector corresponding to the to-be-encoded data, and different encoded codewords corresponding to the to-be-encoded data with different numbers of information bits have different numbers of information bits.

14. The method of claim 13, wherein a number of information bits of the to-be-encoded data is less than or equal to N; the to-be-encoded data includes first to-be-encoded data, the first to-be-encoded data includes K information bits, and K<N; and the acquiring the check code vector of the to-be-encoded data based on the to-be-encoded data includes:
performing a matrix multiplication operation on the K information bits of the first to-be-encoded data based on K sets of target encoding vectors in a first generator matrix in a one-to-one correspondence manner, so as to obtain K sets of check code sub-vectors, wherein the first generator matrix includes N sets of encoding vectors, and the N sets of encoding vectors are in one-to-one correspondence with N information bits; and
performing a bitwise exclusive-or operation on the K sets of check code sub-vectors, so as to obtain a first check code vector, wherein the first check code vector is used for an accuracy check of the first to-be-encoded data.

15. The method of claim 14, wherein the to-be-encoded data includes second to-be-encoded data, and the second to-be-encoded data includes N information bits; and the acquiring the check code vector of the to-be-encoded data based on the to-be-encoded data includes:
performing a matrix multiplication operation on the N information bits of the second to-be-encoded data based on the N sets of encoding vectors in the first generator matrix in a one-to-one correspondence manner, so as to obtain N sets of check code sub-vectors; and
performing a bitwise exclusive-or operation on the N sets of check code sub-vectors, so as to obtain a second check code vector, wherein the second check code vector is used for an accuracy check of the second to-be-encoded data.

16. The method of claim 13, wherein a number of information bits of the to-be-encoded data is less than or equal to N; the to-be-encoded data includes first to-be-encoded data, the first to-be-encoded data includes K information bits, and K<N; the acquiring the check code vector of the to-be-encoded data based on the to-be-encoded data includes:
performing a matrix multiplication operation on the K information bits of the first to-be-encoded data based on K sets of target encoding vectors in a second generator matrix in a one-to-one correspondence manner, so as to obtain K sets of check code sub-vectors, wherein the second generator matrix comprises N+Q sets of encoding vectors, N sets of encoding vectors in the N+Q sets of encoding vectors are in one-to-one correspondence with N information bits, and the N sets of encoding vectors comprise the K sets of target encoding vectors; and
acquiring a first check code vector according to the K sets of check code sub-vectors and Q sets of encoding vectors in the second generator matrix, wherein the first check code vector is used for an accuracy check of the first to-be-encoded data.

17. The method of claim 16, wherein the to-be-encoded data includes second to-be-encoded data, and the second to-be-encoded data includes N information bits; and the acquiring the check code vector of the to-be-encoded data based on the to-be-encoded data includes:
performing a matrix multiplication operation on the N information bits of the second to-be-encoded data based on the N sets of encoding vectors in the second generator matrix in a one-to-one correspondence manner, so as to obtain N sets of check code sub-vectors; and
acquiring a second check code vector according to the N sets of check code sub-vectors and the Q sets of encoding vectors in the second generator matrix, wherein the second check code vector is used for an accuracy check of the second to-be-encoded data.

18. The method of claim 13, further including:
reading to-be-decoded data from the memory, wherein the to-be-decoded data includes information bits and check bits, and a plurality of pieces of to-be-decoded data have different numbers of information bits; and
acquiring decoded data corresponding to the information bits of the to-be-decoded data based on the to-be-decoded data.

19. The method of claim 18, wherein a number of the information bits in the to-be-decoded data is less than or equal to N, and a number of the check bits is equal to Q; the to-be-decoded data includes first to-be-decoded data, the first to-be-decoded data includes K information bits and Q check bits, and K<N; and the acquiring decoded data corresponding to the information bits of the to-be-decoded data based on the to-be-decoded data includes:
performing a matrix multiplication operation on K+Q bits in the first to-be-decoded data based on K+Q sets of target decoding vectors in a check matrix in a one-to-one correspondence manner, so as to obtain a syndrome vector of the Q check bits, wherein the check matrix includes N+Q sets of decoding vectors, the N+Q sets of decoding vectors are in one-to-one correspondence with N information bits and the Q check bits, and the syndrome vector is used to correct an error code in the first to-be-decoded data; and
acquiring decoded data corresponding to the K information bits of the first to-be-decoded data when the syndrome vector is a zero vector.

20. The method of claim 19, wherein the to-be-decoded data includes second to-be-decoded data, and the second to-be-decoded data includes N information bits and Q check bits; and the acquiring decoded data corresponding to the information bits of the to-be-decoded data based on the to-be-decoded data comprises:
performing a matrix multiplication operation on N+Q bits in the second to-be-decoded data based on the N+Q sets of decoding vectors in the check matrix in a one-to-one correspondence manner, so as to obtain a syndrome vector of the Q check bits; and
acquiring decoded data corresponding to the N information bits of the second to-be-decoded data when the syndrome vector is a zero vector.
